(19) United States
(12) Patent Application Publication
(10) Pub. No.: US 2012/0228455 A1
(43) Pub. Date: Sep. 13, 2012

(54) FASTENING ELEMENT FOR FASTENING FRAME ELEMENT TO MOUNTING PLATE, FRAME ELEMENT AND INSTALLATION FACILITY

(75) Inventors: Michael FUHRMANN, Tegernheim (DE); Thomas Haller, Samstagern (CH); Rainer Sedlmeier, Regensburg (DE); Xian Chao Wu, Beijing (CN)

(73) Assignee: Siemens Aktiengesellschaft, Munich (DE)

(21) Appl. No.: 13/414,419

(22) Filed: Mar. 7, 2012

(30) Foreign Application Priority Data
Mar. 7, 2011 (DE) 202011003620.0
Mar. 7, 2011 (EP) 11157193

(51) Int. Cl. H05K 7/00

(52) U.S. Cl. 248/302; 248/316.7

(57) ABSTRACT

A frame element of an installation facility is fastened to a mounting plate of an electrical installation by a fastening element having at least two holding elements, arranged adjacent to one another in a shared plane, that can be elastically deformed relative to one another and each including at least one limb. The limbs are embodied such that they face one another along an imaginary straight line within the shared plane and include a segment of minimal spacing along the imaginary straight line. The spacings of the limbs from one another increase in all other segments along the imaginary line from the segment of minimal spacing.

### CROSS REFERENCE TO RELATED APPLICATIONS

This application is based on and hereby claims priority to German Application No. 20 2011 003 620.0 filed on Mar. 7, 2011, and European Application No. 11157193, filed on Mar. 7, 2011, the contents of which are hereby incorporated by reference.

### BACKGROUND

Described below is a fastening element for fastening a frame element of an installation facility, for instance of a switch or a room temperature controller, in order to fasten this and thus the installation facility to a mounting plate of an electrical installation, in particular a flush-mounted electrical installation. Also described is a frame element for fastening an installation facility to a mounting plate of an electrical installation and an installation facility.

In conventional electrical installations, the control functions are fixedly connected to the energy distribution. Subsequent changes are very difficult to implement on account of this. Higher-ranking control functions, such as a central switching of all pools of lights in a building can also only be realized with a very high outlay.

On account of this, certain European organizations convened to find a common standard for the applications in building automation. The main aims of this standard are high user-friendliness and greater flexibility.

For this purpose, leading European companies from the electrotechnical and construction industries signed the official rules and regulations of a new organization, the KNX Association. At the start of the 21st century, the specification of KNX was published, shortly afterwards adopted in the European standard EN 50090 and this standard was subsequently accepted as international standard ISO/IEC 14543-3. The KNX standard is an open standard to which in the meantime almost 100 companies have subscribed worldwide.

KNX is a field bus for building automation and separates the control functions and the energy distribution from one another. All devices are connected to one another by way of a bus and can thus exchange data. The function of the individual bus subscribers is determined by their programming, which can be changed and adjusted at any time. Devices from different manufacturers can be used here in a non-restrictive manner with one another in a system, provided they exhibit the corresponding certification by the KNX Association.

In particular, KNX is a field bus, which describes how in an installation sensors and actuators can be connected to one another in a housing, and which determines how sensors and actuators have to communicate with one another.

The KNX controls for instance the lighting and blinds and/or shading facilities, building heating and locking and alarm systems. Remote monitoring and control of a building is also possible by KNX. Control takes place here by way of the user him/herself or by way of a computer equipped with corresponding software. KNX is currently installed above all in new residential and purpose-built buildings, but can however also be installed later during the modernization of old buildings. KNX installations are in the meantime not only found in upmarket residential buildings. KNX networks are already also integrated as standard into buildings even in the case of low-cost prefabricated housing.

Installation facilities, e.g. switches, push-buttons, power sockets, temperature controllers or suchlike, which can be fastened to a mounting plate, also referred to as mounting frame, of an electrical installation, in particular a flush-mounted electrical installation, by a frame element, whereby the space requirement is covered by a corresponding control element of the installation facility, are known on the market in various embodiments.

The installation facilities are usually fastened to mounting plates of the electrical installation by way of frame elements, such that they are either screwed thereto and a housing is then pushed thereover or the installation facilities include plug-in connections, such as for instance snap-fit or snap-on connections which are pushed into the mounting plate through slots. Here the plug-in connections provide for a locking between the installation facility and the mounting plate of the electrical installation. If an installation facility is to be changed or removed, it must be detached from the mounting plate. Since the plug-in connections, such as snap-fit or snap-on hooks, are usually made of plastic, there is however the risk that the plug-in connections break away so that they are no longer useable. In particular, tools are needed both for mounting and also dismounting of the installation facilities on/from the electrical installations.

In order to be able to also fasten modern installation facilities, such as for instance room temperature controllers, dimmers etc. to existing mounting plates, in particular mounting plates from different manufacturers, there is a corresponding need for simple fastening options in order to enable a rapid and simple fastening of frame elements of installation facilities, such as for instance room temperature controllers, in accordance with the KNX standard.

### SUMMARY

Accordingly, described below is a simple and cost-effective fastening element for a simple fastening of a frame element of an installation facility and thus of an installation facility to a mounting plate of an electrical installation, in particular a flush-mounted electrical installation.

Features and details apply here which are described in conjunction with the fastening element, naturally also in conjunction with the frame element and the installation facility, and vice versa in each instance, so that reference is and/or can always be made alternately with respect to the disclosure relating to the aspects of each.

According to the first aspect, the fastening element is embodied so as to fasten a frame element of an installation facility and thus an installation facility to a mounting plate of an electrical installation, in particular a flush-mounted electrical installation. In particular, the fastening element includes two holding elements which are arranged adjacent to one another in a shared plane and can be deformed and/or bent elastically relative to one another. The two holding elements each includes at least one limb, with the limbs being embodied such that they face one another along an imaginary straight line within the shared plane and includes a segment of minimal spacing from one another along the imaginary straight line and the spacings of the limbs from one another increase in all other segments along the imaginary line starting from the segment of minimal spacing.

A fastening element embodied in such a fashion is embodied in a simple and cost-effective fashion and enables a simple and rapid fastening of a frame element of an installation facility and thus of an installation facility to a mounting plate of an electrical installation, in particular a flush-mounted electrical installation. In particular, a fastening element embodied in such a fashion enables the fastening of a frame element of an installation facility and thus of an installation facility to a mounting plate of an electrical installation, in particular a flush-mounted electrical installation, without the need of a tool. The special embodiment of the two holding elements enables the latter to be easily fastened to a correspondingly embodied mounting plate of an electrical installation. The mounting plates, with which these fastening elements can be used, include at least two slots which are separated from one another by a bar. The fastening element is, in other words the two holding elements are, pushed into two slots on the mounting plate, whereby they are braced apart on account of the bar of the mounting plate. This is enabled because the two holding elements are arranged adjacent to one another in a shared plane and can be elastically deformed relative to one another. Each holding element includes at least one limb. These limbs of the holding elements face one another along an imaginary straight line within the shared plane. Here the limbs of the holding elements along the imaginary straight line include a segment of minimal spacing from one another. This segment of minimal spacing may be provided in the central region of the limb. The spacings of the limbs from one another increase in all other segments along the imaginary line starting from the segment of minimal spacing. In other words, the two holding elements and/or the respective limbs of the holding elements lie closer to one another in a central segment than in the outer segments. The limbs of the holding elements approximately form an X, whereby the holding elements are not fastened to one another. This special embodiment of the fastening element, in particular of the holding elements, ensures that when pushing the holding elements into the corresponding slots of a mounting plate, these are initially braced apart from one another. If the holding elements are pushed so far into the corresponding slots of the mounting plate that the segment of average spacing is at the height of the bar of the mounting plate, the two holding elements are braced apart to a maximum. If the two holding elements are pushed further into the slots of the mounting plate, the two holding elements close together. In other words, after the segment of average spacing of the holding element has passed the bar of the mounting plate, the fastening element, on account of the spring force of the two holding elements, pulls independently in the direction of the mounting plate, namely until the frame element, on which the fastening element is arranged, rests on the mounting plate. After initial contact of the limbs of the two holding elements with the bar of the mounting plate and the bracing-apart of the holding elements associated therewith, these remain permanently in contact with the bar of the mounting plate, on account of the spring pre-load of the holding elements, and clasp the same. This ensures a simple and secure fastening of the fastening element and thus of a frame element of an installation facility, such as a switch, push-button, power socket, temperature controller or suchlike, on the mounting plate of an electrical installation, in particular a flush-mounted electrical installation, such as for instance a bus system.

The limbs of the holding element of a fastening element are advantageously embodied such that a first and a second region is formed therebetween, which taper toward the segment of minimal spacing. As a result the insertion of the bar of a mounting plate of an electrical installation, which is located between two slots, also referred to as mounting slots, of a mounting plate, into the first and second region is simplified. As a result of a first region being formed between the two holding elements, the region tapering toward the segment of minimal spacing, it is ensured that the two holding elements can be easily inserted into the slots of the mounting plate of an electrical installation and/or the two holding elements can be easily pushed onto the bar of the mounting plate of an electrical installation. The first region functions like a funnel when inserting the two holding elements into the slots of the mounting plate of an electrical installation. The second region between the two holding elements, which tapers toward the segment of minimal spacing, provides, on account of the tapering and the elastic deformability of the holding elements relative to one another, that the fastening element can be automatically drawn onto the mounting plate of an electrical installation and is securely held on the mounting plate as a result.

According to a further development, provision can be made with a fastening element for the holding elements to be arranged along the imaginary straight line in a mirror-symmetrical fashion. As a result, the insertion of the limbs of the holding element and/or the holding elements into the mounting slot of the mounting plate can be simplified. In particular, the mirror-symmetrical embodiment of the holding elements can prevent a canting of the fastening element when fastening the same to a mounting plate of an electrical installation.

According to another further development, provision can be made with a fastening element for the regions, in other words the first and second region, to taper linearly toward the segment of minimal spacing between the limbs of the holding elements. As a result, the fastening element is securely guided into its mounting position on the mounting plate of an electrical installation. A simple and secure spreading apart of the holding elements from one another is ensured by the linear course of the regions above and below the segment of minimal spacing. On the other hand, the limbs of the holding elements and thus the holding elements close together particularly effectively on account of the linear course of the second region, as a result of which the drawing-on and then holding of the fastening element to the mounting plate of an electrical installation is ensured.

The limbs and/or holding elements advantageously include an arched curve in the region of the segment of minimal spacing. This ensures the particularly simple attachment and/or sliding of the holding elements of the fastening element on the mounting plate of an electrical installation, in particular on the bar of the mounting plate of an electrical installation.

The first region between the limbs of the holding elements of a fastening element advantageously tapers toward the segment of minimal spacing such that the parts of the limb which form the first region form an insertion region for inserting a bar, which is embodied between two mounting slots of the mounting plate. This ensures that the holding elements of the fastening element can be easily inserted into the slots of the mounting plate. It is only after the holding elements have been pushed a little way into the slots of the mounting plate that the limbs of the holding elements contact the bar of the mounting plate. In other words, the tapering of the first region and/or the ever decreasing spacing of the limbs relative to one another means that the already slightly inserted fastening element is centered by the bar of the mounting plate. As a result, the first region between the limbs of the holding element form an in particular funnel-type insertion region in order to insert the bar of a mounting plate.

In general terms, the first region between the two holding elements of the fastening element is the region which, when inserting the fastening element, in particular the two holding elements, into the slots of the mounting plate, initially faces this.

The parts of the limbs forming the first region are advantageously arranged at an angle α of less than 50° relative to one another. As a result, the insertion of the bar of a holding iron and/or the attachment of the two holding elements of the fastening element onto the bar of a mounting plate can be embodied in a particularly simple fashion.

The second region between the limbs advantageously tapers toward the segment of minimal spacing such that the parts of the limb forming the second region form an operating area for holding a/the bar which is embodied between two mounting slots of the mounting plate. As a result, the bar is held particularly effectively. The term operating area refers to the spreading-apart of the two holding elements upon attachment onto the bar of the mounting plate and the elastic deformability of the two holding elements, the fastening element is drawn onto the mounting plate of the electrical installation if the bar of the mounting plate is found on parts of the limb of the two holding elements which form the second region. In other words, the tapering of the second region between the limbs of the holding element toward the segment of minimal spacing enables an active drawing-on of the fastening element and thus of a frame element of an installation facility on the mounting plate of an electrical installation, such as a flush-mounted bus system.

The parts of the limbs of the holding elements of a fastening element which form the second region advantageously form an angle of at least 20° relative to one another in the case of a maximum elastic deformation of the holding elements from one another, on account of the feeding-through of the bar of the mounting plate through the segment of minimal spacing. This provides for pressing-in and/or drawing-on of the bar into the operating area of the fastening element and/or a drawing-on of the fastening element onto the mounting plate of an electrical installation.

According to a further development, provision can be made with a fastening element for the limb in the segment of minimal spacing to form a gap therebetween if the holding elements are relaxed, in other wards are not elastically deformed. This enables a particularly simple attachment of the fastening element onto a mounting plate of an electrical installation. Alternatively, the limbs of the holding element can touch in the segment of minimal spacing.

The limbs of the holding elements of a fastening element advantageously include inner limbs and outer limbs which are connected to one another, whereby the inner limbs of the two holding elements face one another. As a result, a particularly good elastic deformability and stability of the two holding elements is produced.

According to another development, provision can be made with a fastening element for the inner and outer limbs of each holding element in the region of its transition to form an angle of 20° to 60°, in particular of 40° to 50°, therebetween. As a result, the limbs assume a type of wedge profile so that the insertion into the mounting slots is configured particularly easily.

The outer limbs of each holding element are advantageously embodied such that they include an arched free end and an angle greater than 90° is formed in the region of the bend. As a result, the outer limbs of the holding element are inclined relative to one another as a result of which the pre-load on one another is increased.

According to a further development, provision can be made with a fastening element for the inner and outer limbs of each holding element to be embodied relative to one another such that the holding elements in a lateral view each includes an essentially D-shaped contour. Holding elements embodied as such have a high stability.

The inner limbs of each holding element of a fastening element are advantageously arched at their ends facing away from the respective outer limbs in a direction at right angles to the plane of the holding elements by 180° such that they form an arched element which connects the two inner limbs to one another. This provides for a reinforcement of the fastening element so that the holding force of the frame element on the mounting plate is increased. Furthermore, the fastening element can be easily fastened to a frame element of an installation facility, such as a switch, a push-button, a power socket, a temperature controller or such.

The minimal inside radius of the arched element of a fastening element advantageously corresponds to three times the diameter of the limbs of the holding element of the fastening element. As a result, a particularly good reinforcement is achieved. In particular, it is advantageous if the minimal inside radius of the arched element corresponds at least to three times the diameter of the limbs of the holding elements of the fastening element, in particular to the wire gauge of the limb of the holding element of the fastening element. This provides an optimal value between the necessary installation space and a voltage distribution. The fastening element is advantageously embodied from a metal wire.

According to a further development, provision can be made with a fastening element for the fastening element to be embodied in one piece, in particular monolithically. As a result, the number of components for mounting a frame element on a mounting plate of an electrical installation device is minimal. Furthermore, the manufacture of the fastening element is simplified and cost-effective. A fastening element of this type likewise ensures high rigidity and stability of the holding elements and of the further components of the fastening element.

A fastening element advantageously includes fastening elements for the force-fit and/or bonded fastening on the frame element. The fastening can take place by screw connections. Furthermore, the fastening element can be fastened to the frame by suitable force and/or bonded connections such as rivets, welding, adhesives for instance.

The fastening element can advantageously be connected to the frame element of an installation facility by hot stamping. As a result, a particularly simple and stable connection is achieved between the fastening element and the frame element of an installation facility.

According to the second aspect, a frame element of an installation facility, in particular a switch, a push-button or a room temperature controller, includes at least one fastening element attached thereto, which is embodied in accordance with the first aspect. A frame element with at least one fastening element embodied according to the first aspect enables a simple fastening of the frame element and thus of an installation facility on a mounting plate of an electrical installation, in particular a flush-mounted electrical installation.

The frame element may be embodied to receive an installation facility, which can be electrically connected to the electrical installation when the frame element is fastened to the mounting plate of an electrical installation.

According to a further development, provision can be made with the frame element for an intermediate element, in particular an intermediate plate, to be arranged on the frame element, the intermediate plate being used as a spacing element between the frame element and the electrical installation. The frame element and thus the installation facility can herewith be attached at an optimal spacing from the electrical installation or the wall in which the electrical installation is arranged.

According to the third aspect, an installation facility includes a frame element for fastening the installation facility to a mounting plate of an electrical installation, whereby the frame element is embodied according to the second aspect.

The installation facility may be for instance a switch, a push-button, a power socket, a temperature controller or suchlike, which can be fastened to a mounting plate of an electrical installation, in particular a flush-mounted electrical installation, by the frame element. An installation facility with a frame element of this type, which includes at least one fastening element embodied in accordance with the first aspect, enables a simple fastening of the installation facility to a mounting plate of an electrical installation, in particular a flush-mounted electrical installation.

According to a further development, provision can be made with the installation facility for the frame element to be an integral part of the installation facility. This means that the frame element may be part of the housing of the installation facility or forms the housing of the installation facility. The frame element may be monolithically manufactured with the housing of the installation facility.

The frame element is advantageously embodied to receive a functional element, which can be electrically connected to the electrical installation when the frame element is fastened to the mounting plate of an electrical installation.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a lateral view of a fastening element,

FIG. 2 is a top view of the fastening element according to FIG. 1,

FIG. 3 is a perspective view of the fastening element according to FIG. 1,

FIG. 4 is a perspective view of a rear of an installation facility with the fastening element fastened thereto,

FIG. 5 is a perspective view of an installation facility with the fastening element fastened thereto and a mounting plate arranged on an electrical installation,

FIG. 6 is a perspective view, which shows an initial step of mounting an installation facility on a mounting plate,

FIG. 7 is a perspective view which shows an intermediate step of mounting the installation facility according to FIG. 6 on the mounting plate,

FIG. 8 is a perspective view of a mounting plate, on which an installation facility is mounted,

FIG. 9 is a lateral view onto an installation facility, which is mounted to a mounting plate of an electrical installation by the fastening element, and

FIG. 10 is a lateral view onto another installation facility, which is mounted on a mounting plate of an electrical installation by the fastening element.

### DETAILED DESCRIPTION OF THE PREFERRED EMBODIMENT

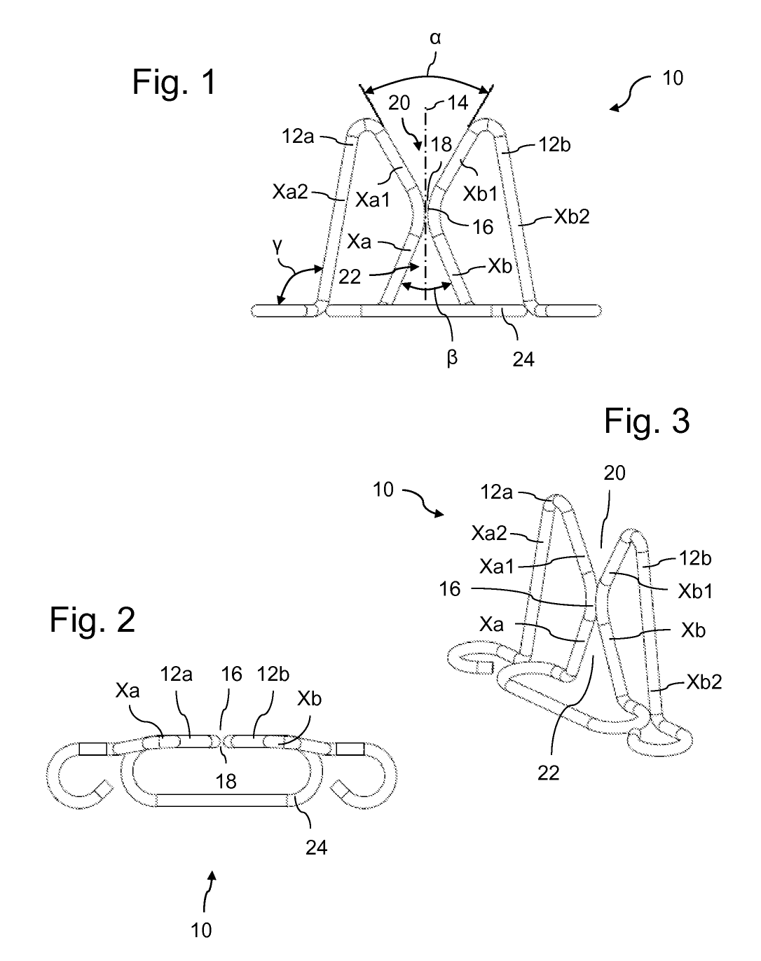

Elements with the same function and mode of operation are provided with the same reference characters in FIGS. 1 to 10 respectively.

FIG. 1 shows a lateral view of a fastening element 10. In FIG. 3, the fastening element 10 is shown in a perspective view. The fastening element 10 is embodied integrally and/or monolithically from a metal wire and includes two holding elements 12a, 12b. The holding elements 12a, 12b are arranged adjacent to one another in a shared plane and can be deformed and/or bent elastically relative to one another, in particular spring-elastically. Each holding element 12a, 12b includes a limb Xa, Xb. The limbs Xa, Xb are embodied such that they face one another along an imaginary straight line 14 within the plane and include a segment 16 of minimal spacing from one another along the imaginary straight line 14 and that the spacings of the limbs Xa, Xb from one another increase in all other segments along the imaginary line from the segment 16 of minimal spacing. In particular, the holding elements 12a, 12b are arranged in a mirror-symmetrical fashion along the imaginary line 14. In the region of segment 16 of minimal spacing, the limbs Xa, Xb are spaced from one another, i.e. a small gap 18 is formed between the limbs Xa, Xb in the segment 16 of minimal spacing. A first region 20 and a second region 22 are formed between the limbs Xa, Xb, each of which tapers linearly toward the segment 16 of minimal spacing. The fastening element 10 may be embodied such that the limbs Xa, Xb of the two holding elements 12a, 12b include inner Xa1, Xb1 and outer Xa2, Xb2 limbs, which are connected to one another such that the holding elements 12a, 12b in a lateral view each essentially adopt a D-shaped contour and are arranged in a mirror-symmetrical fashion along the imaginary line 14. The inner Xa1, Xb1 and outer limbs Xa2, Xb2 form an angle of 20° to 60°, such as 40° to 50°, in the region of their transition. The inner limbs Xa1, Xb1 are arched at their ends facing away from the respective outer limbs Xa2, Xb2, i.e. by about 180° in a direction at right angles to the plane of the holding element such that they form an arched element 24 which connects the two inner limbs Xa1, Xb1 to one another, as seen in FIG. 2, in which the fastening element 10 is shown in a top view. The holding elements 12a, 12b include a certain elastic pre-load in a direction relative to one another, i.e. if the holding elements 12a, 12b are spread apart, in other words arched or pressed away from the imaginary line 14, these revert back into their original position.

In particular, the first region 20 is embodied between the two holding elements 12a, 12b as an insertion region 20, which is embodied to insert a bar and/or for attachment to a bar which is disposed between two mounting slots of a subsequently described mounting plate, of a so-called mounting frame. The inner limbs Xa1, Xb1 form an angle α of less than 50° in the insertion region 20. The second region 22 between the two inner limbs Xa1, Xb1 is embodied as an operating area 22 which is embodied to hold the bar of the mounting plate. The inner limbs Xa1, Xb1 form an angle β of greater than 20° relative to one another, such as 45° in the operating area 22. The outer limbs Xa2, Xb2 are embodied such that they include an arched, free end, and an angle γ of greater than 95°, such as 100°, is formed in the region of the bend. This provides for an additional reinforcement and stability of the fastening element 10. The minimal inner radius of the arched element 24 amounts to at least three times the wire gauge of the metal wire. This represents an optimal value for the compromise between required installation space for inserting the fastening element 10 and a voltage distribution when mounting frame parts.

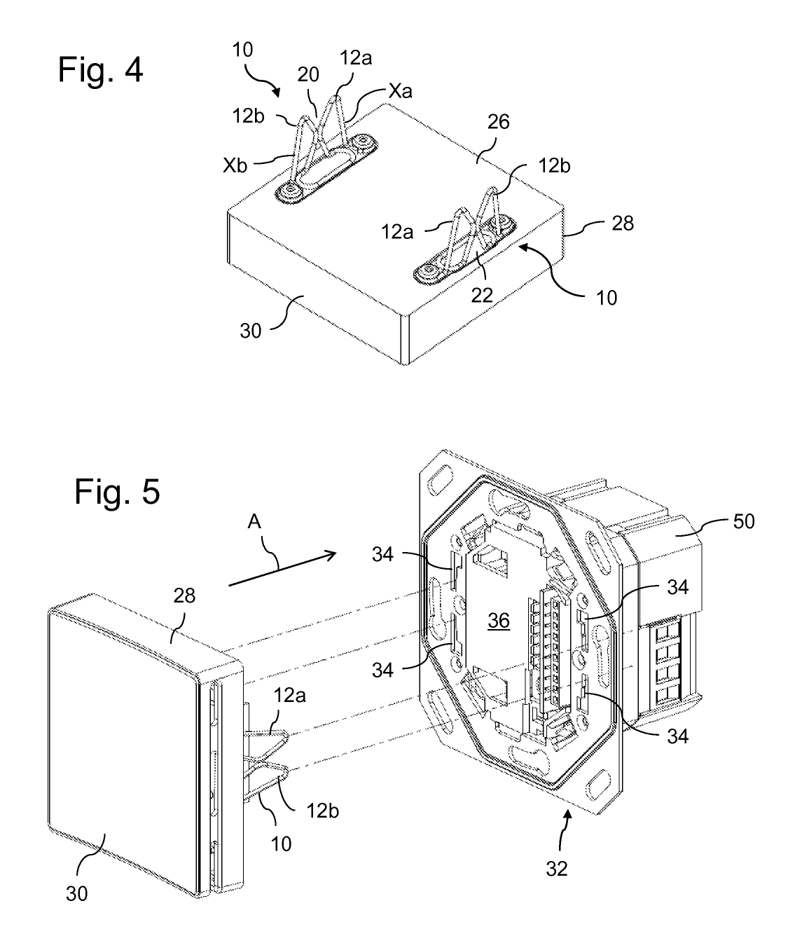

FIG. 4 shows a perspective view of a rear 26 of an installation facility 30 with fastening element 10 fastened thereto.

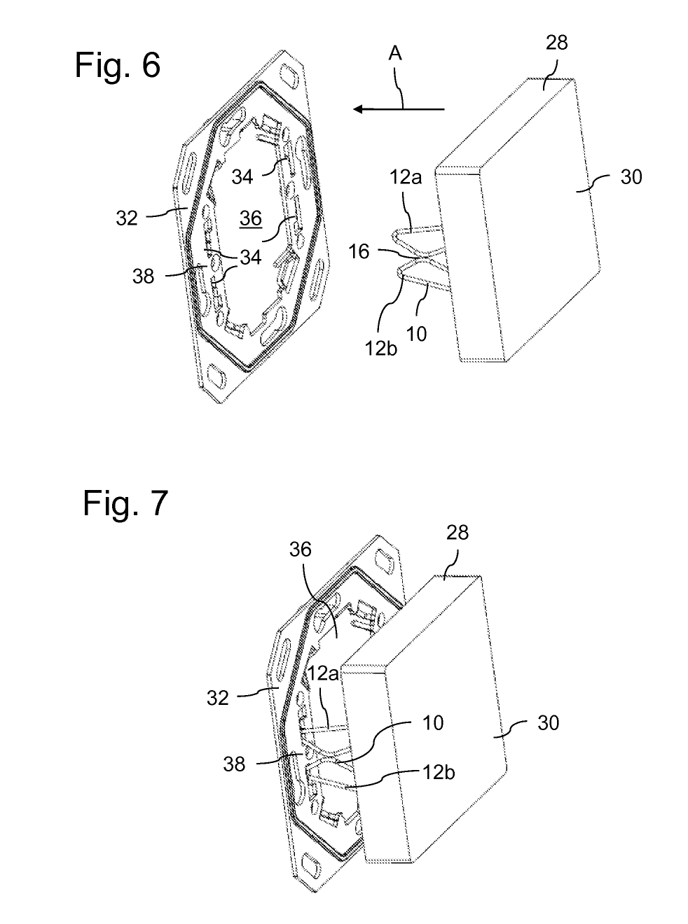

As shown in FIG. 4, the fastening element 10 is found at two points on the rear 26 of the frame element 28 of the installation facility 30, which can be embodied for instance as a KNX room temperature controller. I.e. the fastening element 10 protrude from the side 26 of the frame element 28 which is found in the mounted state on a mounting plate 32 of an electrical installation 50 and/or a wall of a building or suchlike which are visible in FIG. 5 or 6. Two fastening elements 10 are provided for an effective and consistent hold of the frame element 28 and thus of the installation facility 30 on the mounting plate 32. For simplification only mounting by a fastening element 10 is described since this is identical for both. The fastening element 10 is fixedly connected to the frame element 28, in particular the rear 26 of the frame element 28 by hot stamping. More precisely, the free ends of the outer limbs Xa2, Xb2, are connected to the frame element 28 such that the arched element 24 rests on the frame element 28. As a result, the limbs Xa, Xb are essentially at right angles from the rear 26 of the frame element 28 and are supported thereupon.

The mounting plate 32 can be fastened on a corresponding point of a wall of a building, whereby the electrical installation 50 to be connected is found in a wall socket, in a conventional manner attached by screws. Since the mounting of a mounting plate 32 is sufficiently known per se, a description of the mounting of the same on the wall, the wall socket and/or the electrical installation 50 is omitted. For simplification, the mounting plate 32 is shown in the non mounted state in the subsequent FIGS. 5 to 8.

As shown in FIGS. 5 and 6, the mounting plate includes two pairs of slots 34 which are spacing from one another, which are disposed on opposite sides of the mounting plate 32 with a recess 36 for contacting the electrical installation 50 therebetween. Mounting plates 32 for electrical installations 50, for instance bus systems, usually include slots 34 of this type, since the fastening of a frame element 28 of an installation facility 30 on the mounting plate 32 takes place depending on the construction type either by way of screws or by push-fit connections with plug-in connections which are pushed through slots 34. The fastening element 10 can therefore also be used in known mounting plates 32 without any problem.

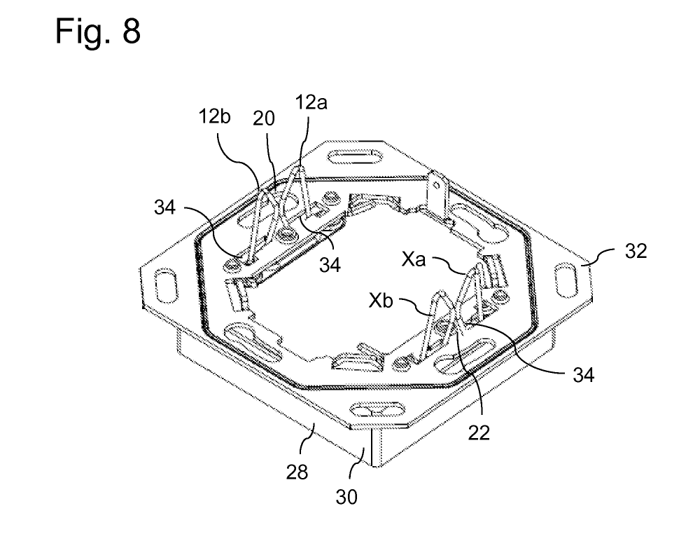

In order to mount the installation facility 30, the frame element 28 of the installation facility 30 is moved forward with the rear 26 onto the mounting plate 32 such that a limb Xa, Xb is moved and/or pushed into a corresponding slot 34 of the mounting plate 32 in each instance. The mounting direction is specified in FIGS. 5 and 6 by arrow A. Here bars 38 of the mounting plate, which are found between the slots 34, are inserted into the insertion region 20 of the fastening element 10 and when further attaching the installation facility 30 onto the mounting plate 32 are pushed through the segment 16 of minimal spacing between the holding elements 12a, 12b, as can be seen in FIG. 7. Since the segment 16 of minimal spacing between the holding elements 12a, 12b and/or the limbs Xa, Xb of the holding elements 12a, 12b is narrower than the bars 38 between the slots 34, the holding elements 12a, 12b are pushed apart. As the operating area 22 extends toward the arched element 24 of the fastening element 10 relative to the mounting direction A, the bottleneck, i.e. the segment 16 of minimal spacing, must be overcome upon attachment in order to press the holding elements 12a, 12b and/or the limbs Xa, Xb of the holding elements 12a, 12b apart by the bars 38 between the slots 34. Once the bars 38 between the slots 34 have passed the segment 16 of minimal spacing of the limbs Xa, Xb of the holding elements 12a, 12b and are thus in the operating area 22, the limbs Xa, Xb move apart from one another again on account of their spring-elastic embodiment and/or extension. On account of the particularly expanding molding of the holding elements 12a, 12b in the operating area 22 viewed in the mounting direction A, the holding elements 12a, 12b pull the frame element 28 and thus the installation facility resting 30 on the frame element 28 onto the bar 38 and thus onto the mounting plate 32. As a result, the installation facility 30 is pulled onto the mounting plate 32, pushed against this and/or held thereagainst. The fastening element 10 therefore provides for an active drawing-on of the room temperature controller 30 on the mounting plate 32 and/or electrical installation 50. The holding elements 12a, 12b go back to their original position in the space of a wall socket and/or electrical installation 50 behind the mounting plate 32, as can be seen in FIG. 8. The installation facility 30 is thus pulled by the fastening element 10 into its final mounting position and held there. As a result it is possible for the installation facility 30 not to have to be mounted with a force which may possibly cause damage. This is particularly important in the case of touch-sensitive displays of installation facilities 30, such as for instance room temperature controllers, since these cannot be pushed onto a mounting plate 32 with too much force effort. The special molding of the operating area 22 between the holding elements 12a, 12b also allows the installation facility 30 to be detached from the mounting plate 32 with a specific force outlay, which is so great that an excessively easy removal of the same is prevented but is not so minimal that it wobbles. In the lowest installation position, removal forces of at least 10 N are needed with an overlap between the fastening element 10 and the mounting plate 30 of 1.5 times the wire gauge. However depending on the installation position, removal forces of a maximum of 40N are needed. The parts of the limbs Xa, Xb forming the second region 22 include an angle β of at least 20° relative to one another with a maximum elastic deformation of the holding elements 12a, 12b from one another on account of passing the bar 38 of the mounting plate 32 through the segment 16 of minimal spacing.

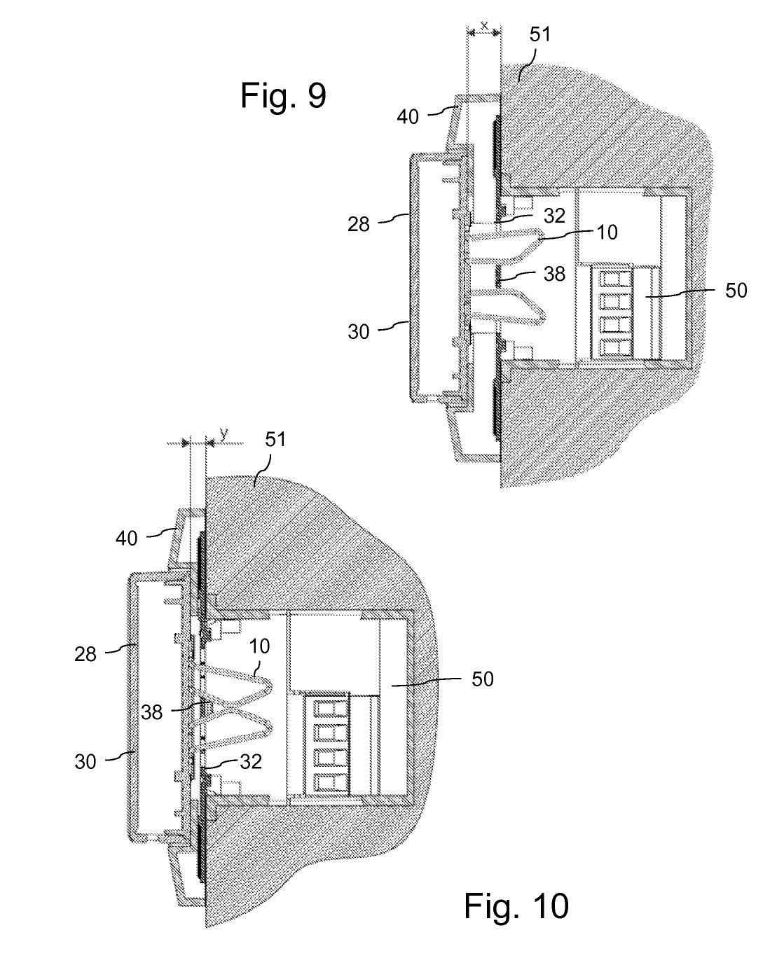

FIG. 9 shows a lateral view onto an installation facility 30, which is mounted on a mounting plate 32 of an electrical installation 50 by fastening element 10. FIG. 10 shows a lateral view onto another installation facility 30, which is mounted on a mounting plate 32 of an electrical installation 50 by fastening element 10. An intermediate element 40, here in the form of an intermediate plate, is arranged in both FIGS. 9 and 10 on the respective frame element 28, the intermediate plate being used as a spacing element between the respective frame element 28 and the electrical installation 50. The frame element 28 and thus the installation facility 30 can herewith be attached at an optimal spacing from the electrical installation 50 or the wall 51, in which the electrical installation 50 is arranged. In FIG. 9 the intermediate element 40 is embodied larger than the intermediate element 40 in FIG. 10. As a result, the installation facility 30 in FIG. 9 is arranged further from the mounting plate 32 of the electrical installation 50 than in FIG. 10. This is indicated by the plotted spacings x and y. In FIG. 9, the illustrated fastening element 10 is not completely pushed into the slots 34 of the mounting plate 32. The bar 38 of the mounting plate 32 therefore pushes the holding elements 12a, 12b apart. On account of the elastic bendability of the holding elements 12a, 12b, these clamp the bar 38 and thereby hold the installation facility 30 fixedly to the mounting plate 32. The intermediate element 40 is also used here to ensure that the installation facility 30 does not tip, in other words the intermediate element 40 centers the installation facility 30 on the wall 51 and/or the mounting plate 32. In FIG. 10, the intermediate element 40 is embodied smaller. The installation facility 30 is arranged closer to the mounting plate 32. The illustrated fastening element 10 is completely inserted into the slots 34 of the mounting plate 32 and as a result holds the installation facility 30 particularly securely on the mounting plate 32.

In other words, depending on the type of frame element, an intermediate element in the form of a design frame can be mounted between the frame element and the mounting plate. This can involve the design frame being pressed from the rear of the frame element against the mounting plate or against the wall. With a corresponding overlap between the housing of the frame element and the design frame, the design frame can slots, through which the holding elements of the at least one fastening element are pushed. Since different manufacturers use intermediate elements and/or design frames with different heights, height differences of the frame elements, i.e. differences of up to 5 mm in a dimension in the mounting direction can be realized with the fastening element. The holding elements furthermore fulfill their holding function even with slightly offset and/or skew attachment. Fastening options other than hot stamping for fastening a frame element are naturally also possible, such as for instance soldering, screwing, adhesion or suchlike. The fastening element may include fastening elements for the force-fit and/or bonded fastening to the frame element. The limbs of the holding elements may also touch in the segment of minimal spacing. The inner limbs do not need to taper linearly toward the segment of minimal spacing, but can instead have a convex form.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1. A fastening element for fastening a frame element of an installation facility to a mounting plate of an electrical installation, comprising:
two holding elements arranged adjacent to one another in a shared plane, elastically deformable relative to one another and each having at least one limb, to provide limbs facing one another along an imaginary straight line within the shared plane, each limb including a segment with minimal spacing from a corresponding segment of a facing limb along the imaginary straight line and spacings of the limbs from one another increasing in all other segments along the imaginary line from the segment of minimal spacing.

2. The fastening element as claimed in claim 1, wherein the limbs of the holding elements define first and second regions formed therebetween which taper toward the segment of minimal spacing.

3. The fastening element as claimed in claim 2, wherein the holding elements are arranged in a mirror-symmetrical fashion along the imaginary straight line.

4. The fastening element as claimed in claim 3, wherein the regions between the limbs taper linearly toward the segment of minimal spacing.

5. The fastening element as claimed in claim 4, wherein a bar is embodied between two mounting slots of the mounting plate, and
wherein the first region between the limbs tapers toward the segment of minimal spacing such that first parts of the limbs forming the first region form an insertion region for inserting the bar between the two mounting slots of the mounting plate.

6. The fastening element as claimed in claim 5, wherein the first parts of the limbs forming the first region are arranged at an anglea) of less than 50° from one another.

7. The fastening element as claimed in claim 6, wherein the second region between the limbs tapers toward the segment of minimal spacing such that second parts of the limbs forming the second region form an operating area for holding the bar between the mounting slots of the mounting plate.

8. The fastening element as claimed in claim 7, wherein the second parts of the limbs forming the second region form an angle of at least 20° relative to one another in maximal elastic deformation of the holding elements, on account of the bar of the mounting plate passing through the segment of minimal spacing.

9. The fastening element as claimed in claim 8, wherein the limbs in the segment of minimal spacing form a gap therebetween.

10. The fastening element as claimed in claim 8, wherein the limbs touch in the segment of minimal spacing.

11. The fastening element as claimed in claim 10, wherein the limbs of the holding elements include inner limbs connected to outer limbs, the inner limbs of the two holding elements facing one another.

12. The fastening element as claimed in claim 11, wherein the inner and outer limbs of each holding element form an angle of 20° to 60°, in particular 40° to 50° therebetween in a region of transition.

13. The fastening element as claimed in claim 12, wherein the outer limbs of each holding element include an arched, free end and an angle of greater than 90° is formed in a bend region.

14. The fastening element as claimed in claim 13, wherein the holding elements have an essentially D-shaped contour in a lateral view.

15. The fastening element as claimed in claim 14, wherein the inner limbs of each holding element are arched at ends facing away from the respective outer limbs in one direction at right angles to the shared plane of the holding elements by 180° to form an arched element connecting the inner limbs to one another.

16. The fastening element as claimed in claim 15, wherein a minimal inner radius of the arched element corresponds at least to three times a diameter of the limbs of the holding elements.

17. The fastening element as claimed in claim 16, wherein the fastening element is embodied in one piece, monolithically.

18. The fastening element as claimed in claim 17, wherein the fastening element is embodied from a metal wire.

19. The fastening element as claimed in claim 18, wherein the fastening element is one of a plurality of fastening elements for force-fit and/or bonded fastening to the frame element.

20. The fastening element as claimed in claim 18, wherein the fastening element is connected to the frame element by hot stamping.

21. The fastening element as claimed in claim 11, wherein the inner and outer limbs of each holding element form an angle of 40° to 50° therebetween in a region of transition.

22. A frame element of an installation facility including a switch, a push-button or a room temperature controller, comprising:
at least one fastening element attached thereto, each fastening element including two holding elements arranged adjacent to one another in a shared plane, elastically deformable relative to one another and each having at least one limb, to provide limbs facing one another along an imaginary straight line within the shared plane, each limb including a segment with minimal spacing from a corresponding segment of a facing limb along the imaginary straight line and spacings of the limbs from one another increasing in all other segments along the imaginary line from the segment of minimal spacing.

23. The frame element as claimed in claim 22, wherein the frame element receives the installation facility to electrically connect an electrical installation thereto by fastening the frame element to a mounting plate of the electrical installation.

24. The frame element as claimed in claim 23, further comprising an intermediate plate arranged on the frame element, providing a spacing element between the frame element and the electrical installation.

25. An installation facility fastened to a mounting plate of an electrical installation, comprising:
a frame element having at least one fastening element attached thereto, each fastening element including two holding elements arranged adjacent to one another in a shared plane, elastically deformable relative to one another and each having at least one limb, to provide limbs facing one another along an imaginary straight line within the shared plane, each limb including a segment with minimal spacing from a corresponding segment of a facing limb along the imaginary straight line and spacings of the limbs from one another increasing in all other segments along the imaginary line from the segment of minimal spacing.
